(19) United States
(12) Patent Application Publication
(10) Pub. No.: US 2005/0184406 A1
(43) Pub. Date: Aug. 25, 2005

(54) Semiconductor device

(75) Inventors: Tetsuya Okada, Kumagaya-city (JP); Hiroaki Saito, Ota-city (JP)

Correspondence Address: Barry E. Bretschneider;Morrison & Foerster LLP, Suite 300, 1650 Tysons Boulevard, McLean, VA, 22102, US

(73) Assignee: Sanyo Electric Co., Ltd., Moriguchi-city (JP)

(21) Appl. No.: 11/061,730

(22) Filed: Feb. 22, 2005

(30) Foreign Application Priority Data
Feb. 24, 2004 (JP) 2004-048257

(51) Int. Cl. H01L 31/062

(52) U.S. Cl. 257/928

(57) ABSTRACT

Conventionally, VF and IR characteristics of a Schottky barrier diode are in a tradeoff relation and there is a problem in that an increase in a leak current is unavoidable in order to realize a reduction in VF. To solve the problem, p type semiconductor regions of a pillar shape reaching an n+ type semiconductor substrate are provided in an n− type semiconductor layer. When a reverse voltage is applied, a depletion layer expanding in a substrate horizontal direction from the p type semiconductor regions fills the n− type semiconductor layer. Thus, it is possible to prevent the leak current generated on a Schottky junction interface from leaking to a cathode side. Since an impurity concentration of the n− type semiconductor layer can be increased to a degree at which the depletion layer expanding from the p type semiconductor regions adjacent to each other can be pinched off, it is possible to realize a reduction in VF and it is possible to secure a predetermined breakdown voltage if only the depletion layer is pinched off.

### BACKGROUND OF THE INVENTION

1. Field of the Invention

The present invention relates to a semiconductor device, and in particular to a semiconductor device that realizes a reduction in a forward voltage VF and a reduction in a reverse current IR of a Schottky barrier diode and secures a predetermined breakdown voltage.

2. Description of the Related Art

A Schottky junction formed by a silicon semiconductor substrate and a metal layer has a rectification action because of a barrier thereof. Thus, the Schottky junction is an element that is generally well known as a Schottky barrier diode.

FIGS. 4A and 4B show a conventional Schottky barrier diode.

As shown in FIG. 4A, an n− type semiconductor layer 32 is stacked on an n+ type semiconductor substrate 31, and a Schottky metal layer 36, which forms a Schottky junction with a surface of the n− type semiconductor layer 32, is provided. This metal layer is made of, for example, Ti. Moreover, an Al layer, which serves as an anode electrode 37, is provided to cover an entire surface of the metal layer. A guard ring 34, in which a p+ type impurity is diffused, is provided in an outer periphery of the n− type semiconductor layer 32 in order to secure a breakdown voltage, and a part of the guard ring 34 is in contact with the Schottky metal layer 36. A cathode electrode 38 is provided or a rear surface of the substrate 31.

When the metal and the semiconductor substrate having different work functions are in contact with each other, energy band of the metal and the semiconductor substrate change such that Fermi levels thereof are identical, whereby a Schottky barrier is formed between the metal and the semiconductor layer. A height of this barrier, that is, a difference of the work functions (in this specification, this difference of the work functions will be hereinafter referred to as φBn) is a factor that determines characteristics of the Schottky barrier diode. In addition, this φBn is a value peculiar to metal.

A current flows when a negative voltage is applied to an n type silicon side and a positive voltage is applied to a metal layer side of the Schottky barrier diode. A voltage at this point is a forward voltage VF. On the other hand, conversely, a current does not flow when a positive voltage is applied to the n type silicon side and a negative voltage is applied to the metal layer side. A voltage at this point will be hereinafter referred to as a reverse voltage. It is possible to consider that a Schottky metal layer of the Schottky barrier diode is a pseudo p type region.

Considering a certain Schottky barrier diode, when φBn increases, the forward voltage VF of the Schottky barrier diode increases and, to the contrary, a leak current IR at the time when the reverse voltage is applied decreases. In other words, the forward voltage VF and the leak current IR are in a trade off relation. This technology is described for instance in Japanese Patent Application Publication No. Hei 6-224410 (page 2, FIG. 2).

As shown in FIG. 4B, a structure in which plural p+ type regions 33 are provided in the n− type semiconductor layer 32 is also known. This is a structure in which a depletion layer 50 expands according to a pn junction when the reverse voltage is applied and the depletion layer 50 is pinched off. Since the depletion layer 50 is pinched off, even if the leak current IR occurs in a Schottky junction region, it is possible to prevent leakage to a cathode side. This technology is described for instance in Japanese Patent Application Publication No. 2000-261004 (pages 2 to 4, FIGS. 1 and 3).

As described before, in the Schottky barrier diode shown in FIG. 4A, the forward voltage VF and the leak current IR are in the tradeoff relation in which, when φBn increases, the forward voltage VF increases and the leak current IR decreases. When φBn does not change, values of the forward voltage VF and the leak current IR fluctuate depending on an area of a Schottky junction.

Thus, it is conceivable to reduce a resistance value of a current path by decreasing resistivity ρ of the n− type semiconductor layer 32 to reduce the forward voltage VF. However, in the structure shown in FIG. 4B, the depletion layer 50 is designed to be expanded sufficiently to the n− type semiconductor layer 32 to secure a predetermined breakdown voltage.

For example, when a breakdown voltage is about 40 V, the n− type semiconductor layer 32 requires resistivity of about 1 Ω·cm and, when a breakdown voltage is about 600 V, the n− type semiconductor layer 32 requires resistivity of about 30 Ω·cm. A depth of the p+ type region 33 depends on a breakdown voltage but is about 1 μm in any case.

When the resistivity ρ of the n− type semiconductor layer 32 is reduced, resistivity of the n− type semiconductor layer 32 below the p+ type region 33, which determines a breakdown voltage, also decreases. Therefore, there is a problem in that the extension of the depletion layer 50 is insufficient and the predetermined breakdown voltage can not be secured.

In addition, in the structure shown in FIG. 4B, the depth of the p+ type region 33 is, for example, 1 μm, which is sufficiently small compared with a depth of the n− type semiconductor layer 32. An impurity concentration of the n− type semiconductor layer 32 is set low in order to secure the predetermined breakdown voltage. Thus, there is a problem in that, when a current path is narrowed by providing the p+ type region 33, a reduction in the forward voltage VF does not make progress.

In this way, in the Schottky barrier diode, a Schottky junction area, a Schottky metal layer, resistivity of a semiconductor layer, and the like are selected appropriately such that the Schottky barrier diode has characteristics close to desired characteristics. However, it is extremely difficult to perform control for obtaining a predetermined forward voltage VF characteristic and the leak current IR characteristic and, then, securing a predetermined breakdown voltage. Therefore, under the actual situation, the Schottky barrier diode is designed sacrificing the forward voltage VF characteristic, the leak current IR characteristic or the breakdown voltage more or less.

### SUMMARY OF THE INVENTION

The invention provides a semiconductor device that includes a semiconductor substrate of a first general conductivity type, a semiconductor layer of the first general conductivity type disposed on the semiconductor substrate, a plurality of impurity regions formed in the semiconductor layer and being in contact with the semiconductor substrate, and a metal layer forming a Schottky junction with the semiconductor layer.

### BRIEF DESCRIPTION OF THE DRAWINGS

FIG. 1A is a plan view for explaining a semiconductor device according to an embodiment of the invention.

FIG. 1B is a sectional view for explaining the semiconductor device according to the embodiment of the invention.

FIGS. 2A and 2B are conceptual diagrams for explaining the semiconductor device according to the embodiment of the invention.

FIGS. 3A and 3B are characteristic charts for explaining the semiconductor device according to the embodiment of the invention.

FIGS. 4A and 4B are sectional views for explaining a conventional semiconductor device.

### DETAILED DESCRIPTION OF THE INVENTION

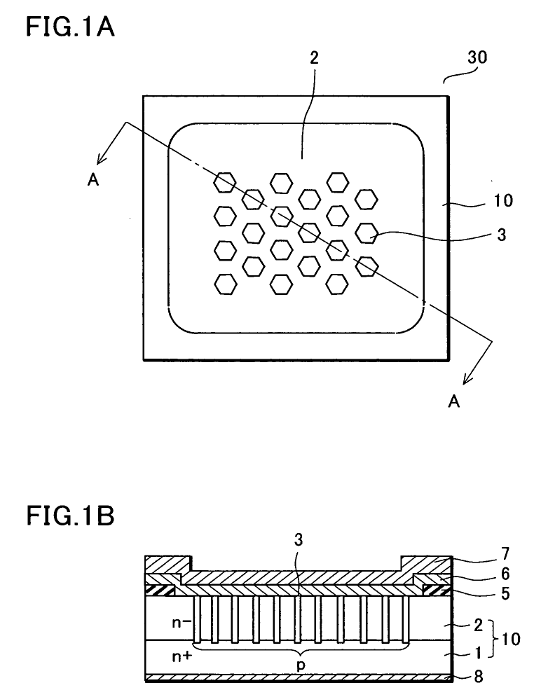

An embodiment of the invention will be explained in detail with reference to FIGS. 1A and 1B to FIGS. 3A and 3B.

FIGS. 1A and 1B show a Schottky barrier diode according to the embodiment of the invention. FIG. 1A is a plan view of the Schottky barrier diode and FIG. 1B is a sectional view along line A-A in FIG. 1A. Note that a Schottky metal layer and an anode electrode on a surface of a substrate are not shown in FIG. 1A.

The Schottky barrier diode of the embodiment includes a one conduction type semiconductor substrate 1, a one conduction type semiconductor layer 2, reverse conduction type semiconductor regions 3, and a Schottky metal layer 6.

A substrate 10 is obtained by stacking the n− type semiconductor layer 2 on the n+ type silicon semiconductor substrate 1 according to, for example, an epitaxial growth method.

The reverse conduction type semiconductor regions 3 are p type semiconductor regions provided in the n− type semiconductor layer 2. For example, a trench is provided in the n− type semiconductor layer 2, polysilicon containing a p type impurity is embedded in the trench, and the p type impurity is diffused around the trench by heat treatment, whereby the p type semiconductor regions 3 are formed. The p type semiconductor regions 3 are provided at a depth at which the p type semiconductor regions 3 penetrate through the n− type semiconductor layer 2 to reach the n+ type semiconductor substrate 1. An impurity concentration of the p type semiconductor regions 3 is about 5×10¹⁴cm⁻³.

Here, the p type semiconductor regions 3 are required to be arranged at equal spaced distances, respectively, such that the depletion layer expands to fill the n− type semiconductor layer 2 when a reverse voltage is applied. A plane shape thereof may be a right hexagon as shown in FIG. 1A.

Note that, if the expansion of the depletion layer is insufficient at least in one section, an electric current leaks from that section to a cathode electrode 8 side. Thus, it is necessary to secure a distance, at which the n− type semiconductor layer 2 is filled with the expansion of the depletion layer when the reverse voltage is applied, among all the p type semiconductor regions 3. A plane shape of the p type semiconductor regions 3 is not limited to the right hexagon as long as the distance can be secured.

More specifically, for example, in a device having a breakdown voltage of about 40 V, a depth of the p+ type semiconductor regions 3 is about 5 μm and an opening width (a diagonal width) of the p type semiconductor regions 3 is, for example, 0.5 μm. The p+ type semiconductor regions 3 are provided about 0.5 μm apart from one another in the n− type semiconductor layer 2. Cross-sectional shapes thereof are pillar shape in FIG. 1B. In this case, resistivity of the n− type semiconductor layer 2 is set to about 0.2 Ω·cm to 0.5 Ω·cm.

In addition, in a device having the breakdown voltage of about 600 V, a depth of the p+ type semiconductor regions 3 is about 50 μm an opening width (a diagonal width) of the p type semiconductor regions 3 is, for example, 1 μm. The p+ type semiconductor regions 3 are provided about 1 μm to 5 μm apart from one another in the n− type semiconductor layer 2. Cross-sectional shapes thereof are pillar shape in FIG. 1B. Resistivity of the n− type semiconductor layer 2 is set to about 5 Ω·cm to 10 Ω·cm.

In this way, according to this embodiment, the p type semiconductor regions 3 are provided at a depth at which the p type semiconductor regions 3 reach the n+ type semiconductor substrate 1. The depletion layer expanding in the horizontal direction of the substrate 10 is pinched off uniformly in the depth direction of the substrate 10. At the time of breakdown, since an electric field intensity is uniform in the substrate depth direction, it is possible to improve the breakdown voltage. In other words, since an impurity concentration of the n− type semiconductor layer 2 can be increased to a degree at which the depletion layer expanding from the p type semiconductor regions 3 adjacent to each other can be pinched off, it is possible to reduce a resistance value of the n− type semiconductor layer 2.

The p type semiconductor regions 3 and the n− type semiconductor layer 2 are exposed on the surface of the substrate 10, and the exposed n− type semiconductor layer 2 serves as a Schottky junction region.

The Schottky metal layer 6 is made of, for example, Mo. The Schottky metal layer 6 is provided on the n− type semiconductor layer 2 and all the p− type semiconductor regions 3, which are exposed by opening an insulating film 5, to form a Schottky junction with the n− type semiconductor layer 2. An Al layer or the like is provided on the Schottky metal layer 6 as an anode electrode 7, and the cathode electrode 8 is provided on a rear surface of the n+ type semiconductor substrate 1.

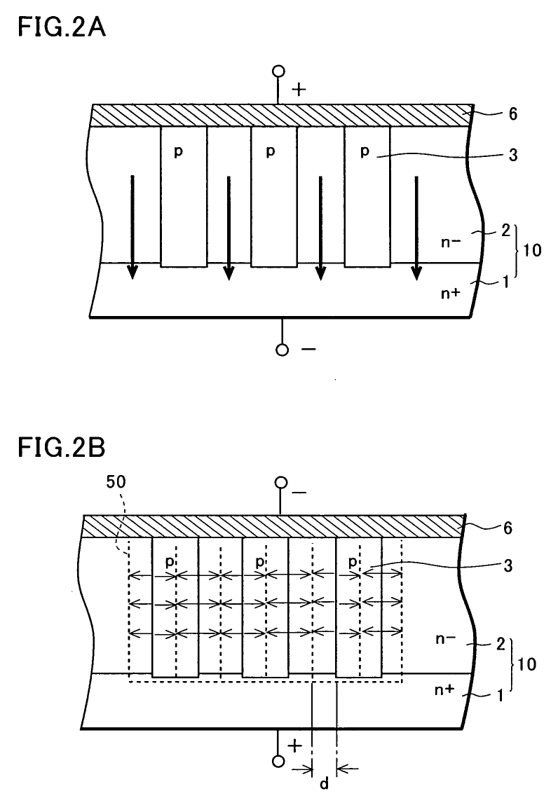

FIGS. 2A and 2B show enlarged views of the vicinity of the p type semiconductor regions 3 when the forward voltage is applied (FIG. 2A) and the reverse voltage is applied (FIG. 2B) in this embodiment, respectively.

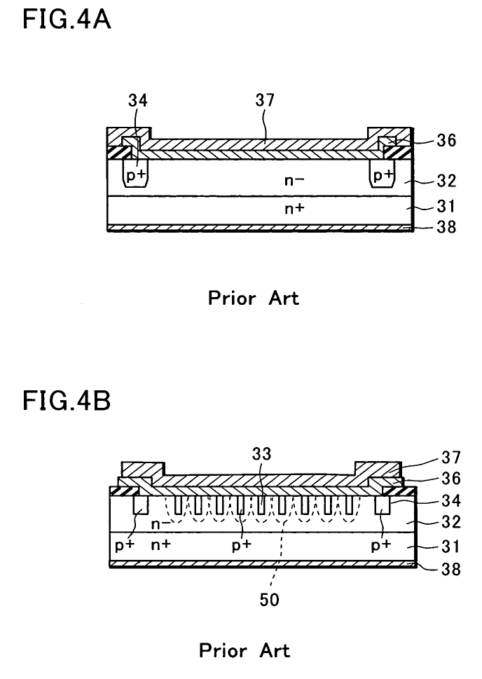

In FIG. 2A, when the forward voltage is applied, the n− type semiconductor layer 2 serves as a current path. In this embodiment, it is possible to reduce resistivity of the n− type semiconductor layer 2 compared with the conventional structure shown in FIG. 4B. Although details will be described later, more specifically, for example, when a breakdown voltage is about 600 V, it is possible to reduce the resistivity to 5 Ω·cm to 10 Ω·cm, which is about one sixth to one third of a breakdown voltage in the conventional structure (FIG. 4B) . Consequently, since a current flows at a low resistance when the forward voltage is applied, it is possible to reduce the forward voltage VF.

On the other hand, as shown in FIG. 2B, the depletion layer 50 expands as indicated by a broken line when the reverse voltage is applied. Here, in this embodiment, as described before, an impurity concentration of the p type semiconductor regions 3 is about 5×10¹⁴cm⁻³. Therefore, when the reverse voltage is applied, the depletion layer 50 also expands to an inner side of the p type semiconductor regions 3, and the n− type semiconductor layer 2 and the p type semiconductor regions 3 change to a depleted region almost entirely.

The depletion layer 50 expands in the horizontal direction of the substrate 10 from the p type semiconductor region 3 and a width (d) of the expansion is substantially uniform along a depth direction of the p type semiconductor region (a vertical direction of the substrate 10).

In general, when the resistivity is too low, the expansion of the depletion layer 50 is insufficient and a breakdown voltage deteriorates. In addition, when an electric field intensity at the time of breakdown is not uniform in the depth direction of the substrate, a breakdown voltage also deteriorates.

However, in this embodiment, the p type semiconductor regions 3 reach the n+ type semiconductor substrate 1. Thus, the depletion layer 50 expands in the horizontal direction of the substrate 10 to be pinched off and pinched off uniformly in the depth direction of the substrate 10. In other words, since the electric field intensity in the depth direction of the substrate 10 is uniform at the time of breakdown, it is possible to improve a breakdown voltage.

In short, it is sufficient that the depletion layer 50 expands in the horizontal direction at the width d. And it is possible to set the resistivity of the n− type semiconductor layer 2 as low as 5Ωcm to 10Ω·cm as described above because the width of the expansion of the depletion layer 50 is small.

In other words, even if the resistivity of the n− type semiconductor layer 2 is decreased in order to secure a predetermined breakdown voltage, it is possible to pinch off the depletion layer 50 sufficiently and reduce the forward voltage VF.

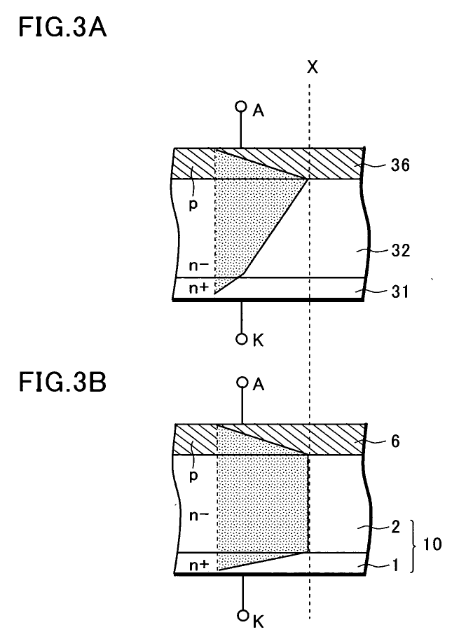

FIGS. 3A and 3B are schematic diagrams showing electric field intensities between an anode electrode and a cathode electrode of the conventional Schottky barrier diode and the Schottky barrier diode of this embodiment, respectively. Note that, since it is possible to consider that the Schottky metal layers 6 and 36 of the Schottky barrier diodes are pseudo p type regions, the Schottky metal layers 6 and 36 are shown as p type regions in the figures.

FIG. 3A shows an electric field intensity in the conventional structure (FIG. 4B) and FIG. 3B shows an electric field intensity in this embodiment (FIG. 1B).

When resistivity of the n− type semiconductor layer 32 of the conventional structure is set to 30 Ω·cm and resistivity of the n− type semiconductor layer 2 of this embodiment is set to 5 Ω·cm, electric field intensities of the conventional structure and this embodiment structure are as indicated by solid lines, respectively. Integrated values of the electric field intensities indicated by hatching are breakdown voltages. In addition, an X line indicates a critical electric field that is an electric field at the time of dielectric breakdown.

As shown in FIG. 3A, in the structure of FIG. 4B, the electric field intensity is far from the point of breakdown near the n+ type semiconductor substrate 31 but reaches the point of breakdown near the surface of the n− type semiconductor layer 32. In this way, when the electric field intensity reaches the X line at least at one point and breaks down, an integrated value of a region indicated by hatching at that point is a breakdown voltage.

In FIG. 4B, the depletion layer 50 is pinched off to prevent a leak current generated in the Schottky junction region from leaking to the cathode side. On the other hand, a breakdown voltage is secured by expanding the depletion layer 50 to the n− type semiconductor layer 32 sufficiently. In other words, the depletion layer 50 also expands to below the p+ type region 33, whereby an electric field intensity is not uniform in the substrate depth direction. Therefore, the electric field intensity has a characteristic of reaching the X line locally and the semiconductor device breaks down, and the breakdown voltage is an integrated value of a region indicated by hatching.

On the other hand, in this embodiment (FIG. 1B), an electric field intensity indicates substantially a uniform value in the substrate vertical direction in the n− type semiconductor layer 2 because of the depletion layer 50 expanding in the horizontal direction of the substrate 10 from the p type semiconductor regions 3. Therefore, as shown in FIG. 3B, the electric field intensity reaches the X line uniformly in the depth direction and the semiconductor device breaks down. In other words, an integrated value of the region indicated by hatching increases compared with that in FIG. 3A, a breakdown voltage is improved so much more for that.

Consequently, in this embodiment, even if an impurity concentration in the n− type semiconductor layer 2 is increased to realize a reduction in the forward voltage VF, it is possible to secure the predetermined breakdown voltage. In addition, since the depletion layer expands in the substrate vertical direction at a uniform width to be pinched off when the reverse voltage is applied, it is possible to suppress the leak current IR that leaks to the cathode electrode side.

Moreover, since only a thickness of the n− type semiconductor layer 2 has to be controlled to secure the breakdown voltage, the control is easy.

According to the embodiment of the invention, even when an impurity concentration of the n− type semiconductor layer is increased and the forward voltage VF is reduced, it is possible to secure the predetermined breakdown voltage.

In short, plural pillar-like p type semiconductor regions reaching the n+ type semiconductor substrate are provided in the n− type semiconductor layer at predetermined intervals, whereby a depletion layer expands from the p type semiconductor regions in a horizontal direction of the substrate when the reverse voltage is applied. In addition, since the depletion layer also expands to the inside of the p type semiconductor regions, the n− type semiconductor layer and the p type semiconductor regions change to a region that is depleted almost entirely. Moreover, since the p type semiconductor regions reach the n+ type semiconductor substrates, the depletion layer expands substantially uniformly along a depth direction of the p type semiconductor layers (a substrate vertical direction) to be pinched off. Thus, it is possible to keep an electric field intensity uniformly in a depth direction of the n− type semiconductor layer. Since the electric field intensity breaks down in that state, it is possible to improve a breakdown voltage.

In short, it is possible to secure the predetermined breakdown voltage if the p type semiconductor regions are arranged at a distance in which the depletion layer expanding in the substrate horizontal direction is pinched off. In other words, spaced distances of the p type semiconductor regions are reduced to a degree at which the depletion layer is pinched off, whereby it is possible to increase an impurity concentration of the n− type semiconductor layer to a concentration that is sufficient for the depletion layer to be pinched off. Therefore, it is possible to reduce a resistance value of the n− type semiconductor layer and reduce the forward voltage VF. Moreover, the leak current IR, which is generated in the Schottky junction region, never leaks to the cathode electrode side because of the depletion layer. Thus, it is possible to substantially reduce the leak current IR.

Since only a thickness of the n− type semiconductor layer has to be controlled to secure the breakdown voltage, the control is easy.

1. A semiconductor device comprising:
a semiconductor substrate of a first general conductivity type;
a semiconductor layer of the first general conductivity type disposed on the semiconductor substrate;
a plurality of impurity regions formed in the semiconductor layer and being in contact with the semiconductor substrate; and
a metal layer forming a Schottky junction with the semiconductor layer.

2. The semiconductor device of claim 1, wherein the impurity regions are configured so that an electric field substantially equal along a direction normal to the semiconductor layer is formed for each of the impurity regions in the semiconductor layer when a reverse voltage is applied between the metal layer and the semiconductor substrate.

3. The semiconductor device of claim 1, wherein the impurity regions have a depth of about 3 μm to about 60 μm.

4. The semiconductor device of claim 1, wherein a resistivity of the semiconductor layer is about 0.2 Ω·cm to about 10 Ω·cm.

5. The semiconductor device of claim 2, wherein the impurity regions are arranged at an equal interval so that the semiconductor layer outside the impurity regions is fully depleted when the reverse voltage is applied.

6. The semiconductor device of claim 2, wherein the impurity regions are arranged so that the whole semiconductor layer is depleted when the reverse voltage is applied.

7. The semiconductor device of claim 2, wherein an impurity concentration of the impurity regions is adjusted so that the whole semiconductor layer is depleted when the reverse voltage is applied.

8. The semiconductor device of claim 7, wherein the impurity concentration of the impurity regions is about 5 10¹⁴ cm⁻³.
